(19) United States
(12) Patent Application Publication
(10) Pub. No.: US 2008/0029762 A1
(43) Pub. Date: Feb. 7, 2008

(54) Test system incorporating a field effect transistor sensor

(76) Inventors: Dale W. Schroeder, Scotts Valley, CA (US); Marshall Thomas DePue, Issaquah, WA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/500,066

(22) Filed: Aug. 7, 2006

(51) Int. Cl. H01L 23/58

(52) U.S. Cl. 257/48

(57) ABSTRACT

A test system in accordance with the invention includes a field effect transistor (FET) sensor that is operable to detect an electric field present in an area located adjacent to a sensor surface of the FET sensor and generate thereby, a change in the drain-source current of the FET sensor. The change in drain-source current is typically detected by a current detector of the test system.

### BACKGROUND

A metal-oxide semiconductor field-effect transistor (MOSFET) is typically a three-terminal device that has been used extensively in a variety of linear applications as well switching applications. The three terminals are: the source, the drain and the gate. As is known, the current which flows in the drain-to-source channel of the MOSFET is a function of a control voltage applied between the gate and source terminals. This operational feature of the device is the primary factor used to design various features such as the geometry, the physical dimensions, and the electrical characteristics of the MOSFET.

For example, the geometry, the location, and the physical dimensions of the gate terminal and its associated gate-to-substrate semiconductor junction are designed to provide optimal control of the drain-source current. FIG. 1 shows a prior art MOSFET 100 with a gate terminal 110 located between a drain terminal 115 and a source terminal 105. The location as well as the dimensions of gate terminal 110 are selected to provide optimal control of the drain-source current I_{ds} under control of an applied gate-to-source biasing voltage V_{gs}.

While the conventional MOSFET has proved suitable for a wide variety of applications, there exist several hitherto undiscovered applications wherein the architecture and design of a conventional MOSFET may prove unsatisfactory.

### SUMMARY

A test system in accordance with the invention includes a field effect transistor (FET) sensor that is operable to detect an electric field present in an area located adjacent to a sensor surface of the FET sensor and generate thereby, a change in the drain-source current of the FET sensor. The change in drain-source current is typically detected by a current detector of the test system.

### BRIEF DESCRIPTION OF THE DRAWINGS

Many aspects of the invention can be better understood with reference to the following drawings. The components in the drawings are not necessarily to scale. Instead, emphasis is placed upon clearly illustrating the principles of the invention. Moreover, in the drawings, like reference numerals designate corresponding parts throughout the several views.

FIG. 1 shows a prior art metal oxide semiconductor field effect transistor (MOSFET).

FIG. 2 shows a first exemplary embodiment of a field effect transistor (FET) sensor in accordance with the invention.

FIG. 3 shows a second exemplary embodiment of a FET sensor in accordance with the invention.

FIG. 4 shows a first exemplary test setup using the FET sensor of FIG. 3.

FIG. 5 shows a second exemplary test setup using the FET sensor of FIG. 3.

FIG. 6 shows a first exemplary embodiment of a FET sensor array in accordance with the invention.

FIG. 7 shows a second exemplary embodiment of a FET sensor array in accordance with the invention.

FIG. 8 shows an exemplary device under test (DUT)—an LCD panel incorporating a thin film transistor (TFT) array for driving a corresponding array of LCD pixel units.

FIG. 9 shows a few components of an LCD pixel unit.

FIG. 10A shows a side-view of the FET sensor array of FIG. 6 configured for testing a TFT array.

FIG. 10B shows a top-view of the test setup of FIG. 10A.

FIG. 10C shows a side-view of a first alternative embodiment of the FET sensor array of FIG. 6 configured for testing a TFT array.

FIG. 10D shows a side-view of a second alternative embodiment of the FET sensor array of FIG. 6 configured for testing a TFT array.

FIG. 11A shows a side-view of the FET sensor array of FIG. 7 for testing a TFT array.

FIG. 11B shows a top-view of the test setup of FIG. 11A.

FIG. 12A shows a side-view of an alternative implementation of the FET sensor array of FIG. 7 for testing a TFT array.

FIG. 12B shows a top-view of the test setup of FIG. 12A.

FIG. 13 shows a flowchart of a method of testing a DUT using a FET sensor in accordance with the invention.

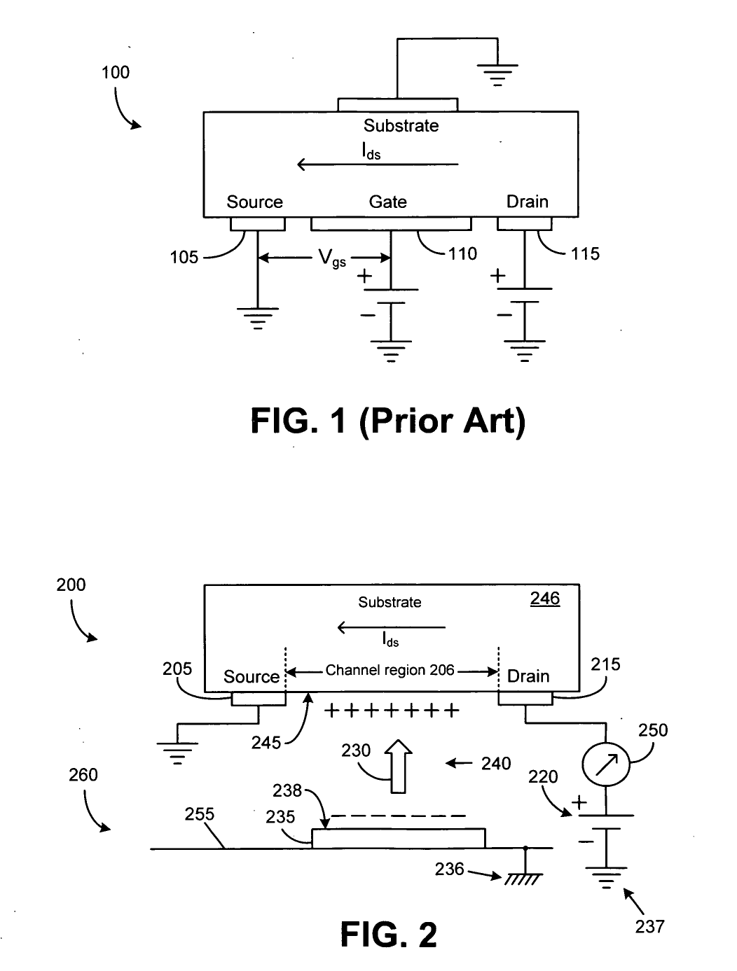

### DETAILED DESCRIPTION

The various embodiments in accordance with the invention generally describe a field effect transistor (FET) sensor that can be used to detect an electric field present in an area located external to the FET sensor.

In one exemplary application, the FET sensor is used for testing a thin film transistor (TFT) located in a liquid crystal display (LCD) pixel unit of an LCD panel. Testing of the TFT is carried out by biasing the TFT so as to charge a capacitor that is also a part of the LCD pixel unit. When charged, the capacitor produces an electric field, which is sensed by the FET sensor and used as a test parameter for characterizing the TFT.

When the capacitor is charged from an alternating current (AC) signal source, such as a frequency generator for example, the electric field produced by the capacitor is referred to herein as a dynamic electric field. However, when the charge remains relatively unchanged over a period of time, such as when the capacitor is charged from a direct current (DC) source, a battery for example, the electric field produced by the capacitor is referred to herein as a static electric field. Consequently, it will be understood that in accordance with the invention the capacitor produces a dynamic electric field in one embodiment and a static electric field in another embodiment. The dynamic electric field is further produced, in one exemplary embodiment, by switching a TFT in an on-off manner. In this particular embodiment, the TFT is configured to couple a DC source and/or an AC source to the capacitor.

For ease of description, the static and dynamic electric fields will be collectively referred to hereinafter by the general term “electric field” and it will be understood that one or both types of electric fields are incorporated into this term.

The FET sensor described above may be further configured as one of an array of FET sensors incorporated into a contactless test system for concurrently testing multiple TFTs of a TFT array of the LCD panel.

FIG. 2 shows a first exemplary embodiment of a field effect transistor (FET) sensor 200 in accordance with the invention. FET sensor 200 includes a source terminal 205 that is coupled to a substrate 246 via a source-substrate semiconductor junction (not shown) as is known in the art. FET sensor 200 further includes a drain terminal 215 separated from source terminal 205 by a channel region 206. Drain terminal 215 is coupled to substrate 246 via a drain-substrate semiconductor junction (not shown) that is also known in the art. However, FET sensor 200 does not include a gate terminal as would be generally present in a conventional FET. On the other hand, substrate 246 has a sensor surface 245 that is configured for detecting an electric field 230 present adjacent to sensor surface 245, for example, in an area 240 located between FET sensor 200 and a device under test (DUT).

Electric field 230 is generated by the DUT, which may be broadly defined as any object that is configurable to generate an electric charge on a surface of the object. Some non-exhaustive examples of DUTs include: a) an LCD panel b) a printed circuit board (PCB) c) a PCB assembly d) a semiconductor substrate and e) an integrated circuit (IC). Furthermore, area 240 is composed of a vacuum, a gas, a liquid or a combination thereof. When gas or liquid is used, for example, a suitable container (not shown) is used to enclose area 240 and hold the gas or liquid.

In the exemplary embodiment shown in FIG. 2, the DUT is an LCD panel 260. LCD panel 260 includes an LCD pixel unit 235 containing a capacitor (not shown) that is selectively charged by a TFT (not shown) so as to produce an electric charge on surface 238 of LCD pixel unit 235. The electric charge is detected by FET sensor 200 via area 240. In this exemplary embodiment, area 240 is composed of air. LCD panel 260 is maintained at a floating potential, which is represented by virtual ground 236.

FET sensor 200 can be implemented in various alternative embodiments. A non-exhaustive list of embodiments includes: a depletion mode FET, an enhancement mode FET, a metal oxide semiconductor filed effect transistor (MOSET), and a junction FET (JFET). Each one of these embodiments may be packaged in several alternative ways, such as by using a metal can package, a thin film package, or a plastic package. Also, sensor surface 245 may encompass an entire external surface of substrate 246, or just a portion of an external surface of substrate 246.

Operation of FET sensor 200 will now be described using FIG. 2. A forward voltage bias is applied between drain terminal 215 and source terminal 205 so as to generate a drain-source current I_{ds}. The biasing is carried out by electrically coupling drain terminal 215 to a positive voltage potential such as that provided by a positive terminal of a biasing source 220 referenced to earth ground 237. The drain-source current I_{ds} is typically detected by a current detector. In certain embodiments, the current detector is embedded inside FET sensor 200; while in other embodiments the current detector is external to FET sensor 200. When embedded inside FET sensor 200, the current detection may be carried out for example, by measuring a voltage drop across the drain and source terminals of FET sensor 200. When external to FET sensor 200, various types of current detectors may be used including, for example, a current meter, a multimeter, an ammeter, an inductive current probe, and a thermal current probe.

In the exemplary embodiment shown in FIG. 2, a current meter 250 is inserted in the connection path to measure forward current flow. Source terminal 205 is electrically coupled to earth ground 237.

In other embodiments, the biasing polarity may be reversed, depending on the nature of FET sensor 200. For example, an enhancement mode device may be biased different to a depletion mode device.

When biased in a linear mode of operation such that drain-source current I_{ds} varies linearly, FET sensor 200 is operative as a linearly-variable resistor. However, in contrast to a conventional FET, the amplitude of the drain-source current I_{ds} in FET sensor 200 is not merely influenced by biasing source 220, but also further influenced by electric field 230, which is produced by the potential difference between virtual ground 236 and earth ground 237. Consequently, a change in the electric field strength of electric field 230 results in a change in drain-source current I_{ds}.

Electric field 230 is a bipolar electric field with a positive charge formed on sensor surface 245 of FET sensor 200 and a negative charge formed on surface 238 of LCD pixel unit 235. The negative charge on surface 238 is generated as a result of charge storage in the capacitor (not shown) of LCD pixel unit 235. The charge storage is affected by turning ‘on’ the TFT (not shown) inside LCD pixel unit 235. The charge storage aspect will be described below in further detail using FIG. 9.

In one exemplary test procedure, sensor surface 245 of FET sensor 200 is positioned about 100 μm from surface 238 of LCD pixel unit 235. The TFT inside LCD pixel unit 235 is initially set to an ‘off’ state. Under this condition, quiescent drain-source current I_{ds} of FET sensor 200 is measured using current meter 250. The TFT is then turned ‘on’ thereby inducing charge storage in the capacitor inside LCD pixel unit 235, which in turn generates the negative charge on surface 238. The resulting change in field strength of electric field 230 causes a change in drain-source current I_{ds} inside FET sensor 200, which is measured using current meter 250. The change in amplitude of drain-source current I_{ds}, which is directly proportional to the change in electrical conductivity of channel region 206 of FET sensor 200, is used as a quantitative measure of the field strength of the electric field 230.

In one exemplary application of the test procedure described above, the change in amplitude of drain-source current I_{ds} is merely used to verify that the TFT has transitioned from the ‘off’ state to the ‘on’ state. In another exemplary application, the change in amplitude of drain-source current I_{ds} is used to quantify the amplitude of the current flow in the TFT when the TFT is in the ‘on’ state. Verifying TFT operation and measuring the current flow in the TFT are merely examples of characterizing a TFT. Other procedures for characterizing the TFT may include placing the TFT in a saturated mode of operation or a switching mode of operation and using FET sensor 200 to detect these states via measurement of electric field 230.

In alternative embodiments, the charge polarities of electric field may be opposite to that shown in FIG. 2. Such polarities may be set by suitably biasing FET sensor 200 with appropriate bias voltages and correspondingly biasing the TFT inside LCD pixel unit 235.

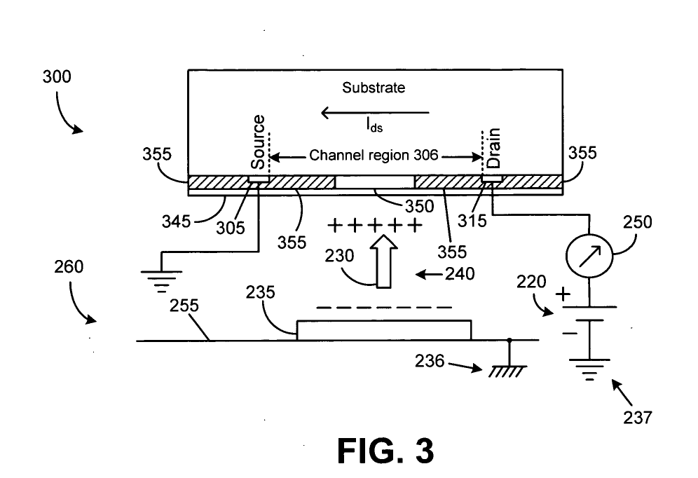

FIG. 3 shows a second exemplary embodiment of a FET sensor 300 in accordance with the invention. FET sensor 300 includes a source terminal 305, a drain terminal 315, and a gate terminal 350. FET sensor 300 further includes a metal sensor plate 345 attached to gate terminal 350. Metal sensor plate 345 is electrically isolated from source terminal 305 and drain terminal 315 by an insulating layer 355. Metal sensor plate 345 is operative to sense electric field 230 present in area 240 and couple the detected voltage into gate terminal 350. The voltage applied to gate terminal 350 operates as a gate control voltage and causes drain-source current I_{ds} of FET sensor 300 to be correspondingly modified. The change in amplitude of drain-source current I_{ds} with reference to quiescent drain-source current I_{ds} provides a measure of the amplitude of the gate control voltage, which, in turn, provides a measurement of the field strength of electric field 230. Typically, the physical dimensions of source terminal 305 and drain terminal 315 are selected to be minimal in comparison to the sensor surface area provided by metal sensor plate 345, thereby maximizing the electric field detection sensitivity of FET sensor 300.

In an alternative implementation, metal sensor plate 345 is replaced by a metal coating applied over insulating layer 355.

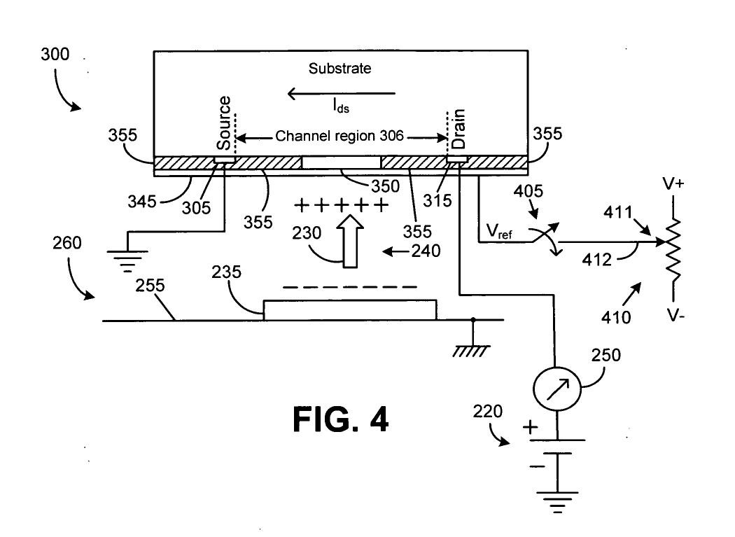

FIG. 4 shows a first exemplary test setup using the FET sensor 300 of FIG. 3. In this exemplary test setup, metal sensor plate 345 is provided a reference voltage bias V_{ref} via a switch 405 and a potentiometer 410. Potentiometer 410 is coupled to a positive voltage at one end of potentiometer 410 and a negative voltage at the other end. Wiper 411 may be positioned closer towards one end to provide a positive V_{ref}, or closer towards the other end to provide a negative V_{ref} that is coupled to switch 405 via link 412. The midway position of wiper 411 corresponds to zero voltage. When switch 405 is in a closed position, the positive V_{ref} or the negative V_{ref}, set via wiper 411, is coupled into metal sensor plate 345.

In one exemplary mode of operation, switch 405 is set to a closed position and wiper 411 adjusted so as to set a desired initial condition of FET sensor 300. For example, wiper 411 may be adjusted so as to set one or more of the following initial conditions: removing effects of static charge that may be present on metal sensor plate 345, setting a desired quiescent drain-source current I_{ds}, setting a desired linear range of operation for drain-source current I_{ds}.

Once the initial conditions have been set, switch 405 is placed in an open-switch condition, whereby reference voltage bias V_{ref} is disconnected from metal sensor plate 345. The charge stored in the capacitor (not shown) inside LCD pixel unit 235 is then changed by operating the TFT (not shown) associated with the capacitor. This procedure, which is described below in further detail using FIG. 9, leads to a change in electric field 230 thereby causing a change in the drain-source current I_{ds} of FET sensor 300. The TFT is then characterized using the measured value of the drain-source current.

In another exemplary mode of operation, the device characteristics of FET sensor 300 may be calibrated by generating a map of V_{ref} versus drain-source current I_{ds} by operating wiper 411 of variable resistor 410 to provide various values of V_{ref}. Once the calibration has been completed, FET sensor 300 may be used for testing a DUT using one or more values of drain-source current I_{ds}.

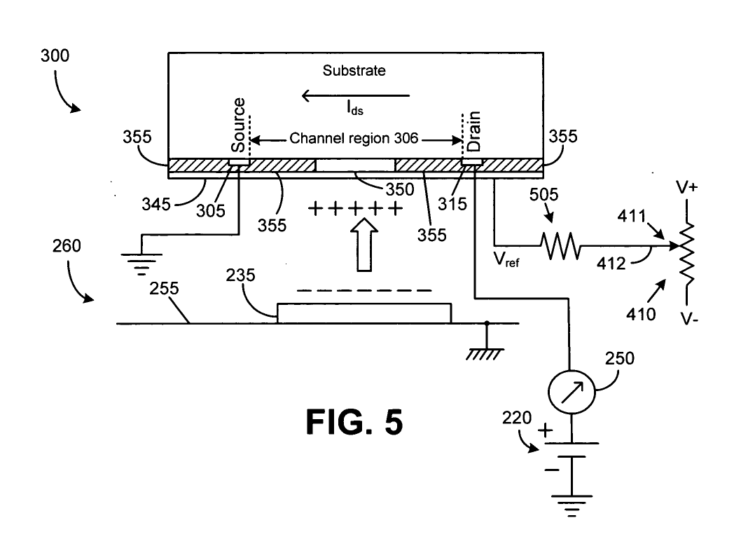

FIG. 5 shows a second exemplary test setup using FET sensor 300 of FIG. 3. In contrast to the first test setup described above using FIG. 4, in this second exemplary test setup, switch 405 is replaced by a resistor 505. Typically, resistor 505 is a high impedance resistor having a resistance value that is comparable to the resistance of switch 405 in an “open” condition. Resistor 505 is operative to providing a bias voltage to metal sensor plate 345 as well as operative to remove any undesirable charge build up that may be present on metal sensor plate 345.

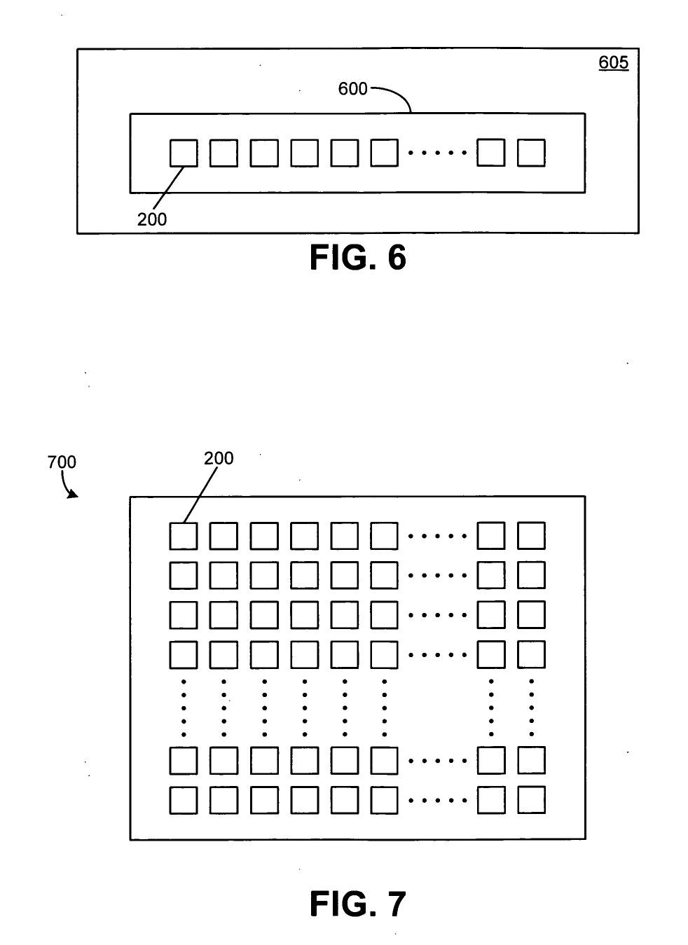

FIG. 6 shows a first exemplary embodiment of a FET sensor array 600 in accordance with the invention. In this exemplary embodiment, FET sensor array 600 contains a single row array of FET sensors, each of which is designated, for purposes of description, as a FET sensor 200, though other FET sensors in accordance with the invention may be used alternatively. Typically, FET sensor array 600 is part of a camera, which is generally referred to herein as an electric field camera 605. Other parts of electric field camera 605, which are not shown in FIG. 6, include, for example, current measurement circuitry, analog-to-digital conversion circuitry, multiplexing circuitry, and positioning servomotors.

FIG. 7 shows a second exemplary embodiment of a FET sensor array 700 in accordance with the invention. In this exemplary embodiment, FET sensor array 700 is formed as a matrix array of FET sensors. Each of the FET sensors has been described above in various embodiments and will not be repeated herein. Typically, FET sensor array 700 is part of an imaging device (not shown) that includes other components.

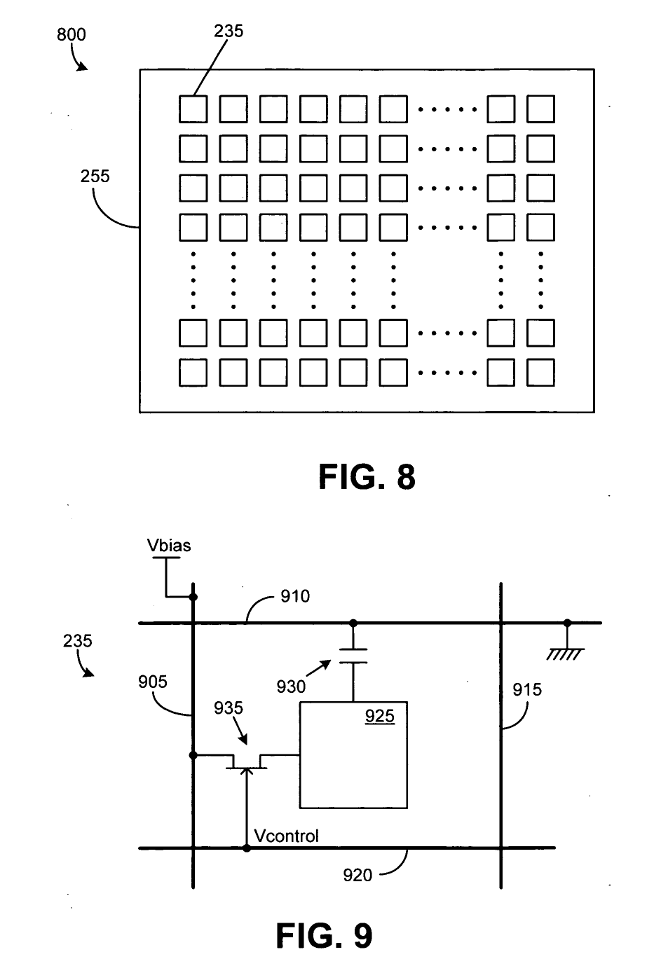

FIG. 8 shows a first embodiment of an LCD panel 800, which constitutes an exemplary device under test (DUT) that can be tested by a test system in accordance with the invention. LCD panel 800 incorporates a matrix array of LCD pixel units, each of which includes a picture element (pixel), a charge storage capacitor and a TFT driver device. Further details of one exemplary unit, LCD pixel unit 235, are provided below.

FIG. 9 shows some exemplary components of individual LCD pixel unit 235. Control lines 905, 910, 915 and 920 are a part of a matrix of control lines that extend to the four edges of LCD panel 800 of FIG. 8. Individual LCD pixel unit 235 includes a pixel 925 that is electrically coupled to horizontal control line 910 via charge storage capacitor 930. Pixel 925 is further coupled to vertical control line 905 and to second horizontal control line 920 via TFT 935, which is operable in part as a switching element to turn pixel 925 on or off. Control line 905 is provided a bias voltage that is coupled to a terminal, for example, the drain terminal, of TFT 935. Control line 920 is selectively provided with a control voltage that is operative to placing TFT 935 in one of an ‘on’ or an ‘off’ state. For example, TFT 935 is placed in the ‘on’ state by providing a positive polarity control voltage at a first instant and placed in the ‘off’0 state by removing the control voltage at a second instant.

When TFT 935 is in the ‘on’ state, pixel 925 is turned on and a charge is coupled into storage capacitor 930. The charge stored in capacitor 930 is the negative polarity charge described above with reference to electric field 230. Consequently, the presence of charge in capacitor 930, which denotes TFT 935 in an ‘on’ state, can be used for characterizing TFT 935.

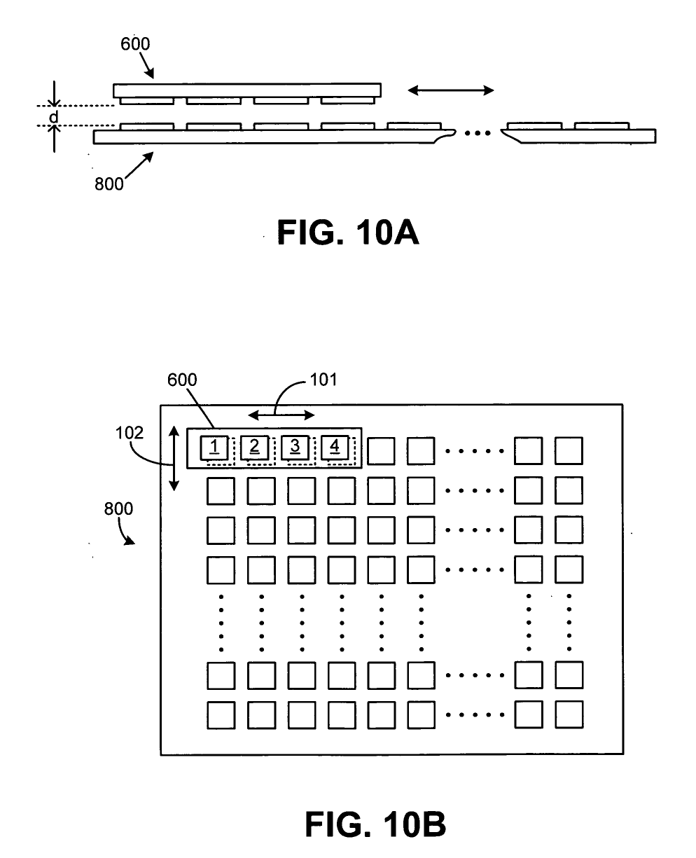

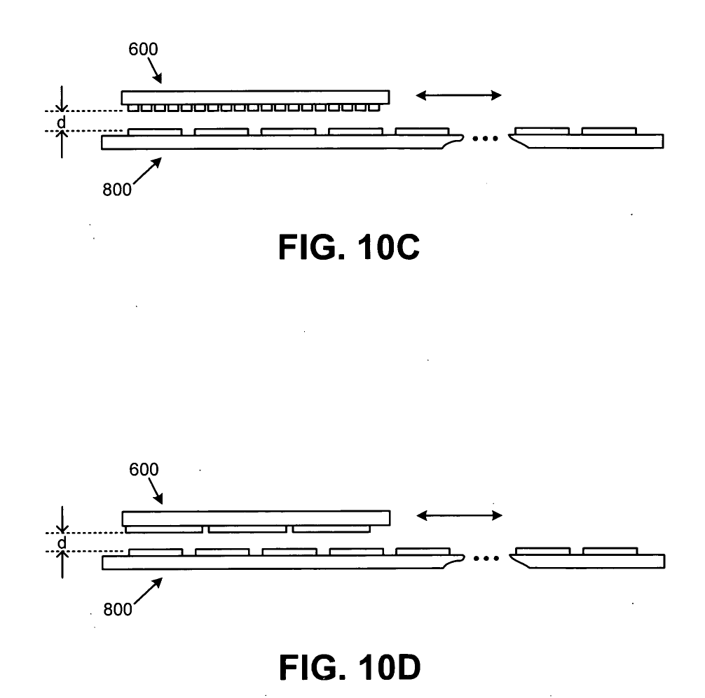

FIG. 10A shows a side-view of a first exemplary test setup using a FET sensor array 600 for testing LCD panel 800 which is the DUT in this example. FIG. 10B shows a top view of FET sensor array 600 positioned above LCD panel 800. The dimensions of each of the individual FET sensors of FET sensor array 600 are selected in accordance with the dimensions of each of the LCD pixel units of LCD panel 800. For example, the perimeter dimensions of each of the FET sensors may be identical to the perimeter dimensions of each of the LCD pixel units, so as to provide a one-to-one coincidence between individual FET sensors and individual LCD pixel units when FET sensor array 600 is positioned over LCD panel 800 as will be described below.

In operation, each of the individual FET sensors of FET sensor array 600 is suitably biased and FET sensor array 600 is initially positioned at a distance ‘d’ above a first group of individual LCD pixel units of LCD panel 800. The first group of LCD pixel units includes LCD pixel units 1-4. In one exemplary test procedure, the TFTs inside half of the first group of LCD pixel units, for example, LCD pixel units 1 and 3, are placed in an ‘on’ condition by providing suitable voltage bias and the TFTs inside the remaining half (LCD pixel units 2 and 4) of the first group of LCD pixel units are placed in an ‘off’ condition. FET sensor array 600 is then used to detect the electric fields generated by the capacitors inside LCD pixel units 1 and 3.

Upon completion of this detection process, the TFTS of LCD pixel units 1 and 3 that were placed in the ‘on’ condition are now placed in an ‘off’ condition and the TFTs of LCD pixel units 2 and 4 are placed in an ‘on’ condition. The test procedure described above is then repeated to test the TFTs of LCD pixel units that are now turned on. The test procedure may be further used to confirm that each of the TFTs in LCD pixel units 1-4 have toggled from an ‘on’ state to an ‘off’ state and vice-versa.

Upon completion of this test procedure, FET sensor array 600 is repositioned at a distance d above a second group of individual LCD pixel units of LCD panel 800 and the test repeated.

It will be understood that additional elements such as image processing circuits, analog-to-digital converters, position sensing circuits, and servomotors, which may be used optionally, are not shown in FIG. 10A and FIG. 10B so as to keep the description focused on the primary aspects of the invention.

In an alternative embodiment, the TFTs of half of all the LCD pixel units of LCD panel 800 are placed in an ‘on’ condition by providing suitable voltage biasing, while the TFTs in the remaining half of all LCD pixel units are placed in an ‘off’ condition. FET sensor array 600 is sequentially moved from one group of individual LCD pixel units of LCD panel 800 to a second group of individual LCD pixel units of LCD panel 800 without transitioning any of the TFTs to the opposite state.

Once the entire LCD panel 800 has been tested a first time in this manner, thereby qualifying half the number of TFTs (the ones turned ‘on’), TFTs that were in the ‘off’ condition are transitioned to the ‘on’ condition and vice versa. FET sensor array 600 is then sequentially moved once again from one group of individual LCD pixel units to another group of individual LCD pixel units and the test repeated to characterize all the TFTs of LCD panel 800 that are now in the ‘on’ state.

FET sensor array 600 may be moved across LCD panel 800 in a scanning pattern that encompasses a horizontal direction indicated by bidirectional arrow 101 and a vertical direction indicated by bidirectional arrow 102. Scanning patterns of various types may be used. Some example patterns include: interlaced scanning, sequential column scanning, sequential row scanning, and random scanning.

FIG. 10C shows a side-view of a first alternative embodiment of the FET sensor array 600 described above using FIG. 10A. In this alternative embodiment, the dimensions of each of the individual FET sensors of FET sensor array 600 are selected to be smaller than the dimensions of each of the LCD pixel units of LCD panel 800. Consequently, a first group of FET sensors is used to test a TFT of a first LCD pixel unit and a second group of FET sensors is used to test a second TFT of a second LCD pixel unit. Using multiple sensors to test a single TFT provides certain advantages. For example, the test results derived from two individual FET sensors may be compared to verify testing accuracy.

FIG. 10D shows a side-view of a second alternative embodiment of the FET sensor array of FIG. 6 configured for testing a TFT array. In contrast to the embodiment of FIG. 10C, the dimensions of each of the individual FET sensors of FET sensor array 600 are selected to be larger than the dimensions of each of the LCD pixel units of LCD panel 800. Consequently, a first FET sensor is used to test a first TFT of a first LCD pixel unit as well as a second TFT of a second LCD pixel unit concurrently. Such a concurrent testing provides certain advantages in testing a TFT array. For example, the larger sensing surface of the individual FET sensors may provide better sensitivity than that obtained with a FET sensor having a smaller sensing surface.

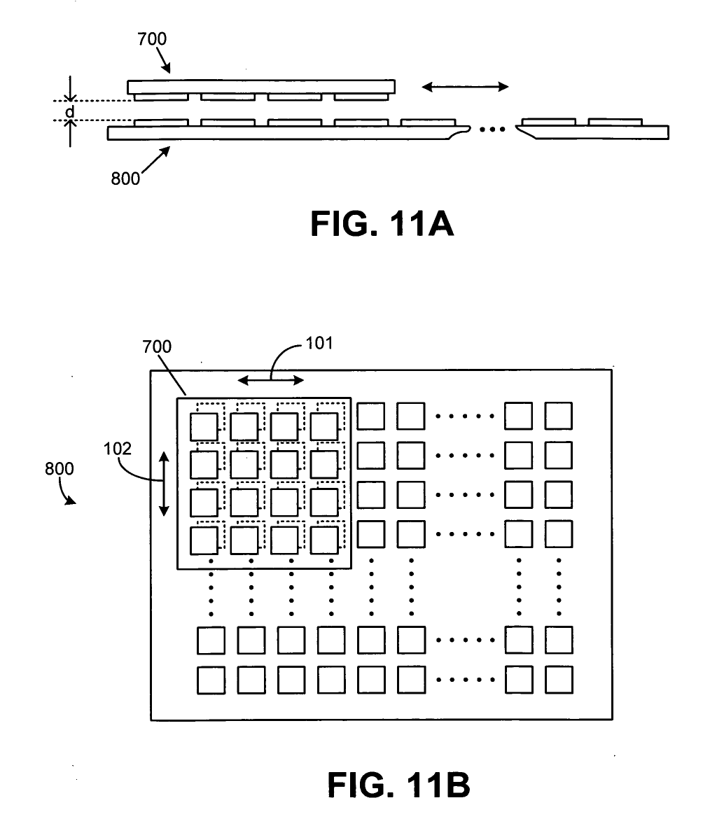

FIG. 11A shows a side-view of a second exemplary test setup using FET sensor array 700 for testing LCD panel 800, which is used here again as an exemplary DUT. FIG. 11B shows a top view of FET sensor array 700 positioned above LCD panel 800. FET sensor array 700 may be operated in a manner similar to that described above with reference to FET sensor array 600. Because FET sensor array 700 covers a large area of LCD panel 800 than the area coverage provided by FET sensor array 600, testing of LCD panel 800 can be completed faster.

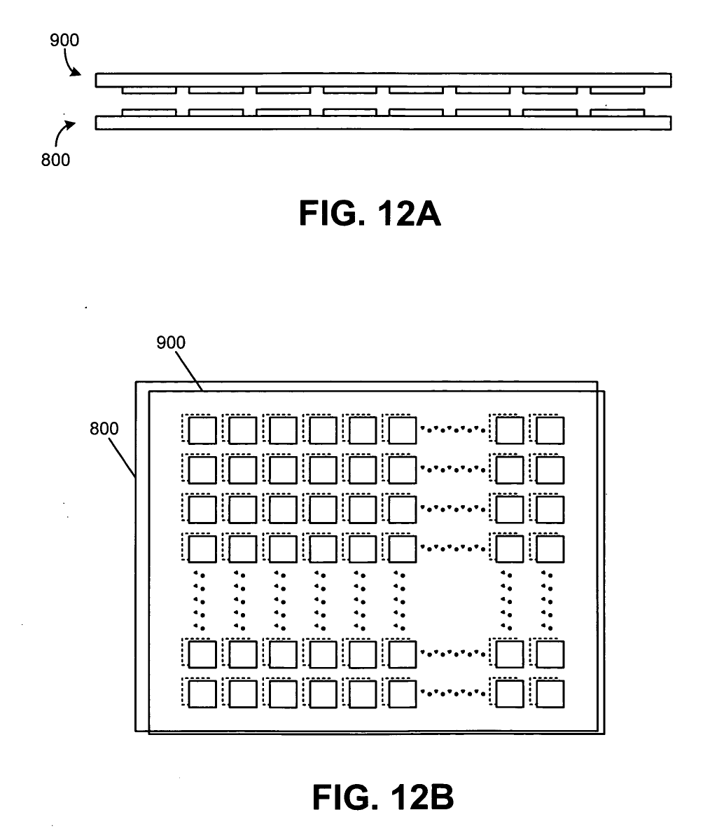

FIG. 12A shows a side-view of a third exemplary test setup using FET sensor array 900 for testing LCD panel 800. FIG. 12B shows a top view of FET sensor array 900 positioned above LCD panel 800. The larger coverage area provided by FET sensor array 900 in comparison to arrays 600 and 700 provides certain advantages. For example, testing time is reduced. Furthermore, FET sensor array 900 may be fixedly positioned above LCD panel 800 thereby avoiding the use of scanning servomotors to move FET sensor array 900 from one location to another above LCD panel 800.

In addition to the operational modes described above using other embodiments, FET sensor array 900 may be further operated in several alternative ways. For example, a time-varying waveform, a square wave for example, may be applied to each of the individual LCD pixel units of LCD panel 800. The time-varying electric fields generated by TFTs in each of the individual LCD pixel units is detected by corresponding sensors in FET sensor array 900 thereby permitting FET sensor array 900 to be used for characterizing the alternating current (AC) parameters of individual LCD pixel units of LCD panel 800.

Additionally, in one alternative embodiment, FET sensor array 900 is coupled to an image processing system (not shown) that is used to implement various image processing procedures such as edge-detection and image-enhancement to detect defective pixels as well as to characterize individual pixels.

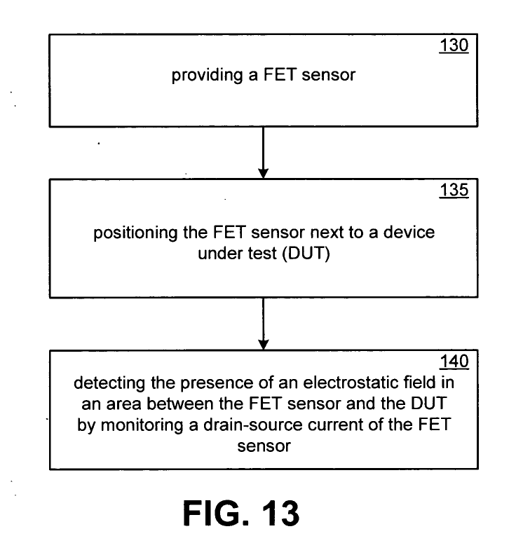

FIG. 13 shows a flowchart of a method, in accordance with the invention, for testing a DUT. In block 130, a FET sensor is provided. The FET sensor has been described above using various figures and will not be repeated herein. In block 135, the FET sensor is positioned next to the DUT. In block 140, an electric field generated by the DUT, is detected in the FET sensor by monitoring a drain-source current I_{ds} in the FET sensor.

The above-described embodiments in accordance with the invention are merely set forth for a clear understanding of the principles of the disclosure. Many variations and modifications may be made without departing substantially from the disclosure. All such modifications and variations are included herein within the scope of this disclosure.

We claim:

1. A test system comprising:
a field effect transistor (FET) sensor operable to detect an electric field present in an area located adjacent to a sensor surface of the FET sensor and generate in response thereof, a change in a drain-source current of the FET sensor; and
a current detector configured to detect the change in the drain-source current.

2. The test system of claim 1, wherein the FET sensor comprises:
a substrate;
a drain junction located in a first region of the substrate; and
a source junction located in a second region of the substrate, the second region separated from the first region by a channel region of the substrate, and wherein at least a portion of the substrate is configured to detect the electric field.

3. The test system of claim 2, wherein the electric field is generated by a charge stored in a capacitor of a liquid crystal display (LCD) pixel unit of an LCD panel, and wherein the area comprises one of a) a vacuum b) air c) a liquid and d) a gas located between the FET sensor and the LCD pixel unit.

4. The test system of claim 3, wherein the FET sensor is a part of a FET sensor array and the LCD pixel unit comprises a thin film transistor (TFT) operative to store the charge in the capacitor of the LCD pixel unit.

5. The test system of claim 3, wherein at least one physical dimension of the FET sensor is determined by a physical dimension of the LCD pixel unit.

6. The test system of claim 2, wherein the electric field is generated by a device under test (DUT) and wherein the area comprises one of a) a vacuum b) air c) a liquid and d) a gas located between the FET sensor and the DUT.

7. The test system of claim 6, wherein the DUT comprises one of a) a liquid crystal display (LCD) panel, b) a printed circuit board (PCB), c) a PCB assembly, d) a semiconductor substrate and e) an integrated circuit (IC).

8. The test system of claim 1, wherein the FET sensor comprises:
a source terminal attached to a first semiconductor junction configured as a source junction;
a drain terminal attached to a second semiconductor junction configured as a drain junction; and
a sensor plate attached to a third semiconductor junction configured as a gate junction, the sensor plate adapted to detect the electric field and induce in response thereof, the change in the drain-source current of the FET sensor.

9. The test system of claim 8, wherein the electric field is generated by a charge stored in a capacitor of a liquid crystal display (LCD) pixel unit of an LCD panel and wherein the area comprises one of a) a vacuum b) air c) a liquid and d) a gas located between the FET sensor and the LCD pixel unit.

10. The test system of claim 9, wherein at least one physical dimension of the sensor plate is determined by a physical dimension of the LCD pixel unit.

11. The test system of claim 9, further comprising:
a voltage source; and
a switch operable to selectively couple the voltage source to the sensor plate.

12. The test system of claim 11, wherein the voltage source provides at least one of a) a direct current (DC) voltage having a positive polarity, b) a DC voltage having a negative polarity, and d) an alternating current (AC) voltage.

13. The test system of claim 11, wherein the voltage source is an adjustable voltage source configured to provide adjustment of at least one of a) an amplitude, b) a polarity, c) a frequency and d) a phase of a reference voltage.

14. A method of testing a device under test (DUT), the method comprising:
providing a field effect transistor (FET) sensor;
positioning the FET sensor next to the DUT; and
detecting the presence of an electric field in an area between the FET sensor and the DUT by monitoring a drain-source current of the FET sensor.

15. The method of claim 14, wherein the DUT comprises a liquid crystal display (LCD) panel.

16. The method of claim 15, further comprising:
turning on a thin film transistor (TFT) of the LCD panel to store a charge in a capacitor of the LCD panel;
measuring a first drain-source current of the FET sensor, wherein the first drain-source current is generated in response to turning on the TFT;
turning off the TFT of the LCD panel;
measuring a second drain-source current of the FET sensor, wherein the second drain-source current is generated in response to turning off the TFT;
using the first and second drain-source currents to characterize the TFT.

17. The method of claim 16, wherein turning on the TFT comprises placing the TFT in one of a saturated mode and a linear mode of operation.

18. The method of claim 14, wherein detecting the presence of the electric field comprises:
applying a voltage to at least a portion of a detection area of the FET sensor; and
obtaining in response thereof, a quiescent drain-source current.

19. The method of claim 18, wherein applying the voltage comprises providing a first voltage having a polarity and a magnitude selected to remove a static charge present on the detection area of the FET sensor.

20. The method of claim 14, wherein the electric field is one of a) a static electric field and b) a dynamic electric field.

21. A method of testing a liquid crystal display (LCD) panel, the method comprising:
providing a field effect transistor (FET) sensor;
positioning the FET sensor next to the LCD panel;
generating an electric field in at least a portion of the LCD panel; and
detecting the electric field by measuring a current flow in the FET sensor.

22. The method of claim 21, wherein generating the electric field comprises turning on a thin film transistor (TFT) of the LCD panel to store a charge in a capacitor of the LCD panel.
